(19) United States
(12) Patent Application Publication
(10) Pub. No.: US 2015/0069339 A1
(43) Pub. Date: Mar. 12, 2015

(54) ORGANIC LIGHT-EMITTING DISPLAY APPARATUS AND METHOD OF MANUFACTURING THE SAME

(71) Applicant: Samsung Display Co., Ltd., Yongin-City (KR)

(72) Inventor: Byung-Uk Han, Yongin-City (KR)

(73) Assignee: Samsung Display Co., Ltd., Yongin-City (KR)

(21) Appl. No.: 14/231,559

(22) Filed: Mar. 31, 2014

(30) Foreign Application Priority Data
Sep. 10, 2013 (KR) 10-2013-0108621

(51) Int. Cl. H01L 51/52; H01L 27/32; H01L 51/56

(52) U.S. Cl. CPC H01L 51/5243; H01L 51/56; H01L 27/32
USPC 257/40; 438/28

(57) ABSTRACT

An organic light-emitting display apparatus including: a first substrate including at least one organic light-emitting diode (OLED); a second substrate facing the first substrate; an inorganic sealant between the first and second substrates and attaching the first and second substrates together; a shock absorber between the first and second substrates and configured to absorb a shock applied to at least one of the first and second substrates; and a block member between the inorganic sealant and the shock absorber and configured to separate the shock absorber from the inorganic sealant, is disclosed.

### CROSS-REFERENCE TO RELATED APPLICATION

This application claims priority to and the benefit of Korean Patent Application No. 10-2013-0108621, filed on Sep. 10, 2013, in the Korean Intellectual Property Office, the entire content of which is incorporated herein by reference.

### BACKGROUND

1. Field

One or more aspects according to embodiments of the present invention relate to an organic light-emitting display apparatus and a method of manufacturing the same.

2. Description of the Related Art

Organic light-emitting display apparatuses provide high-quality features such as wide viewing angles, high contrast ratio, quick response times, and low power consumption. Therefore, organic light-emitting display apparatuses can be used for personal portable devices such as MP3 players or cellular phones, TVs, and the like. Additionally, in response to consumers' demand, thicknesses of some organic light-emitting display apparatuses have been reduced.

However, when the thicknesses of the organic light-emitting display apparatuses are reduced, it is difficult to achieve or secure mechanical reliability of the apparatuses during tests such as a drop test or a twist test. If mechanical reliability is not achieved or secured, a seal of the apparatus is easily broken, even by a minor shock. Accordingly, the lifespan of the organic light-emitting display apparatuses having reduced thickness is decreased.

Because organic light-emitting diodes (OLEDs) that form pixels include organic materials that are vulnerable to moisture and/or oxygen, a sealant is used to protect the OLEDs from moisture and/or oxygen. Thus, a material of the sealant greatly affects mechanical reliability.

### SUMMARY

One or more aspects according to embodiments of the present invention are directed toward an organic light-emitting display apparatus in which shock resistance reliability is improved and attachment between an upper substrate and a lower substrate is prevented from weakening (or an amount or likelihood of such weakening is reduced), and a method of manufacturing the organic light-emitting display apparatus.

Additional aspects will be set forth in part in the description which follows and, in part, will be apparent from the description, or may be learned by practice of the presented embodiments.

According to one or more embodiments of the present invention, an organic light-emitting display apparatus includes: a first substrate including at least one organic light-emitting diode (OLED); a second substrate facing the first substrate; an inorganic sealant between the first and second substrates and attaching the first and second substrates together; a shock absorber between the first and second substrates and configured to absorb a shock applied to at least one of the first and second substrates; and a block member between the inorganic sealant and the shock absorber and configured to separate the shock absorber from the inorganic sealant.

The block member and the inorganic sealant may be formed of a same material.

The block member may be less than or equal to the inorganic sealant in height.

A ratio of a width of the block member to a width of the inorganic sealant may be about 0.05 to about 0.15.

The shock absorber may include an organic material.

The shock absorber may be between the OLED and the inorganic sealant.

A second block member may be between the OLED and the shock absorber.

The substrate may have a trench, and a portion of the shock absorber may be inserted in the trench.

A portion of the block member may be inserted in the trench.

A height of the block member may be greater than a height of the inorganic sealant.

A difference between the height of the block member and the height of the inorganic sealant may be less than a depth of the trench.

A depth of the trench may be in a range of about 1 μm to about 3 μm.

A portion of the block member may be inserted in a support on the first substrate.

A portion of the block member may be inserted in a support on the trench.

The substrate may include a display area including the OLED, and a non-display area surrounding the display area, and a ratio of a width of the inorganic sealant to a width of the non-display area may be about 0.15 to about 0.55.

The first substrate may include a display area including the OLED, and a non-display area surrounding the display area, and a ratio of a width of the shock absorber to a width of the non-display area may be about 0.08 to about 0.2.

According to one or more embodiments of the present invention, a method of manufacturing an organic light-emitting display apparatus includes: providing a first substrate and at least one organic light-emitting diode (OLED) on the first substrate; providing an inorganic sealant, a block member, and a shock absorber on a second substrate; positioning the inorganic sealant on the second substrate to face the first substrate; and attaching the first and second substrates together.

The block member may be between the inorganic sealant and the shock absorber.

The inorganic sealant and the block member may be formed of a same material.

The providing of the shock absorber on the second substrate may include providing the shock absorber at an inner side of the inorganic sealant, and further providing a second block member at an inner side of the shock absorber.

### BRIEF DESCRIPTION OF THE DRAWINGS

These and/or other aspects of embodiments of the present disclosure will become apparent and more readily appreciated from the following description of the embodiments, taken in conjunction with the accompanying drawings in which:

FIG. 1 is a plan view of an organic light-emitting display apparatus according to an embodiment of the present invention;

FIG. 2 is a cross-sectional view of the organic light-emitting display apparatus of FIG. 1 taken along lines II-II′;

FIG. 3 is a cross-sectional view illustrating a portion of an example of an organic light-emitting diode (OLED) of the organic light-emitting display apparatus of FIG. 1;

FIG. 4 is an enlarged cross-sectional view of a portion of the organic light-emitting display apparatus of FIG. 2;

FIG. 5 is a cross-sectional view of an organic light-emitting display apparatus according to another embodiment of the present invention;

FIGS. 6A to 6D are cross-sectional views illustrating a method of manufacturing the organic light-emitting display apparatus of FIG. 2, according to an embodiment of the present invention;

FIG. 7 is a cross-sectional view illustrating an attachment state of a first substrate and a second substrate of an organic light-emitting display apparatus, which, in contrast to embodiments of the present invention, does not include a block member and a second block member;

FIG. 8 is a cross-sectional view of an organic light-emitting display apparatus according to another embodiment of the present invention;

FIG. 9 is an enlarged cross-sectional view of a portion of the organic light-emitting display apparatus of FIG. 8;

FIGS. 10 and 11 are cross-sectional views of organic light-emitting display apparatuses including alternative embodiments of the trench of the organic light-emitting display apparatus of FIG. 8;

FIG. 12 is a cross-sectional view of an organic light-emitting display apparatus according to another embodiment of the present invention; and

FIG. 13 is an enlarged cross-sectional view of a portion of the organic light-emitting display apparatus of FIG. 12.

### DETAILED DESCRIPTION

Reference will now be made in detail to certain embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, expressions such as “at least one of,” when preceding a list of elements, modify the entire list of elements and do not modify the individual elements of the list.

It will be understood that although the terms “first”, “second”, etc. may be used herein to describe various components, these components should not be limited by these terms. These components are only used to distinguish one component from another.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “on” or “formed on,” another layer, region, or component, it can be directly or indirectly on or formed on the other layer, region, or component. That is, for example, intervening layers, regions, or components may or may not be present.

Sizes of elements in the drawings may be exaggerated for convenience of explanation. In other words, because sizes and thicknesses of components in the drawings may be exaggerated for convenience of explanation, the following embodiments are not limited to the sizes and thicknesses depicted in the drawings.

Certain embodiments may be implemented in an order different from those described herein. For example, a specific process order may be performed differently from the order described herein. For example, two consecutively described processes may be performed substantially at the same time (e.g., concurrently or simultaneously) or performed in an order opposite to the described order. Further, the use of “may” when describing embodiments of the present invention refers to “one or more embodiments of the present invention.”

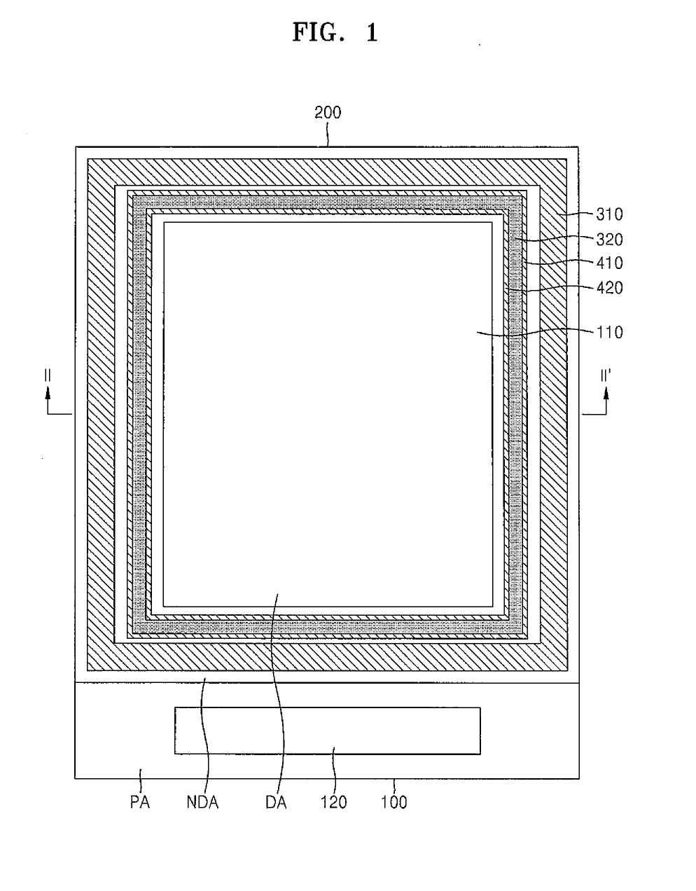

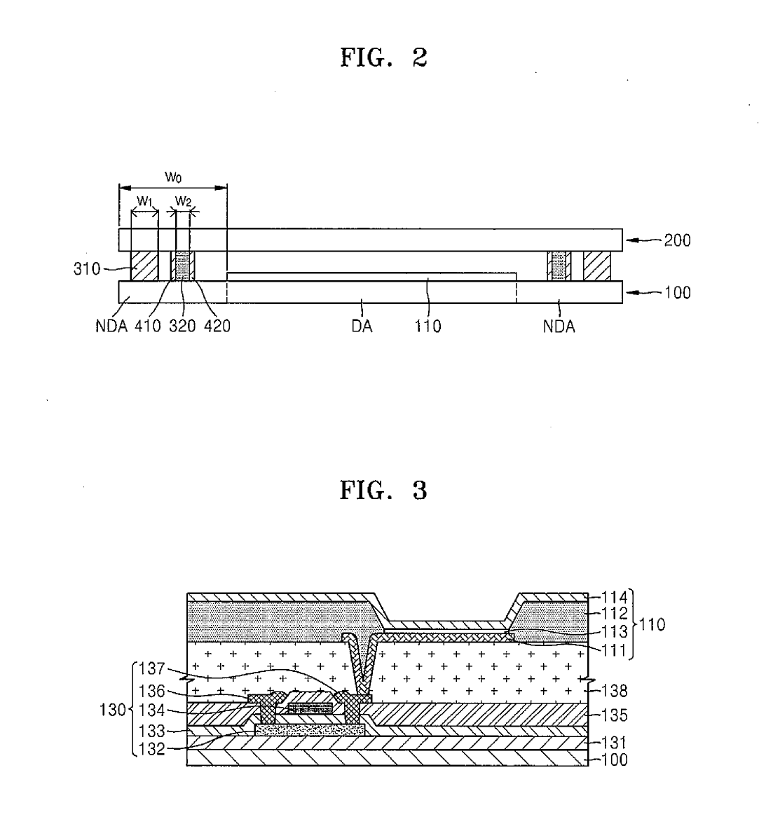

FIG. 1 is a plan view of an organic light-emitting display apparatus according to an embodiment of the present invention. FIG. 2 is a cross-sectional view of the organic light-emitting display apparatus of FIG. 1 taken along line II-II′. FIG. 3 is an enlarged cross-sectional view of a portion of the organic light-emitting display apparatus of FIG. 2.

Referring to FIGS. 1 and 2, the organic light-emitting display apparatus according to an embodiment of the present invention includes a first substrate 100, on which a plurality of light-emitting diodes (LEDs) 110 are formed; a second substrate 200 disposed to face (e.g., facing) the first substrate 100; and an inorganic sealant 310 disposed between the first and second substrates 100 and 200 so as to surround the plurality of LEDs 110.

In the embodiments shown in FIG. 1, the first substrate 100 may include a display area DA, a non-display area NDA around the display area DA, and a pad area PA at a side of the non-display area NDA. The display area DA includes at least one LED 110, for example, the plurality of LEDs 110. The non-display area NDA includes the inorganic sealant 310, a block member 410, and a shock absorber 320. The pad area PA includes a driving circuit 120 for driving the LED 110.

Referring to FIG. 3, the LED 110 is an organic-light emitting diode. The LED 110 may include an anode electrode 111, a cathode electrode 114, and an organic light-emitting layer 113 between the anode electrode 111 and the cathode electrode 114. The organic light-emitting layer 113 is formed in a light-emitting layer (e.g., an area in which the anode electrode 110 is exposed) defined by a pixel-defining layer 112. The organic light-emitting layer 113 may include a hole injection layer (HIL), a hole transport layer (HTL), an electron transport layer (ETL), and/or an electron injection layer (EIL).

A thin film transistor (TFT) 130 for controlling operations and a capacitor that maintains signals may be connected to the LED 110. The anode electrode 111 of the LED 110 may be connected to the TFT 130 via a contact hole in a planarization insulating layer 138. The TFT 130 includes a semiconductor layer 132 providing a source and drain areas and a channel area (e.g., an area between the source and drain areas, such as an intrinsic region); a gate electrode 134 that is insulated from the semiconductor layer 132 by a gate insulating layer 133; and a source electrode 136 and a drain electrode 137 that are connected to the semiconductor layer 132 via contact holes formed in an insulating layer 135 and the gate insulating layer 133. A buffer layer 131 may be between the TFT 130 and the first substrate 100.

Referring back to FIGS. 1 and 2, the second substrate 200 is disposed to overlap at least a portion of the display area DA and the non-display area NDA of the first substrate 100. For example, the second substrate 200 may have a form (e.g., a shape and area) that corresponds to that of the first substrate 100. When the organic light-emitting display apparatus is a top emission type (e.g., a top emission display), the second substrate 200 may be formed of a transparent material such as glass; however, when the organic light-emitting display apparatus is a bottom emission type (e.g., a bottom emission display), the second substrate 200 may be formed of an opaque material.

The inorganic sealant 310 is between the first and second substrates 100 and 200 so as to surround the LED 110, and thus prevents (or reduces) penetration of external moisture or oxygen. The inorganic sealant 310 may include (or be formed of) an inorganic material that may be melted by laser or infrared rays and attach to the first and second substrates 100 and 200. For example, the inorganic material may be glass frit.

In order to reduce a dead space and stabilize attachment, a width w₁ of the inorganic sealant 310 may be about 0.15 to about 0.55 times a width w₀ of the non-display area NDA (e.g., a ratio of the width w₁ of the inorganic sealant 310 to the width w₀ of the non-display area NDA may be about 0.15 to about 0.55). For example, if the width w₀ of the non-display area NDA is in a range of about 1300 μm to about 1700 μm, the width w₁ of the inorganic sealant 310 may be in a range of about 300 μm to about 700 μm.

When there is a possibility of a shock on (e.g., applied to) the organic light-emitting display apparatus, in order to ensure shock reliability, the shock absorber 320 may be disposed between the first and second substrates 100 and 200. If there is a shock on at least one of the first and the second substrates 100 and 200, the shock absorber 320 absorbs the shock (or a portion of the shock) applied on (or to) at least one of the first and second substrates 100 and 200 so as to prevent the inorganic sealant 310 from being damaged (or to reduce an amount or likelihood of such damage), or prevent the attachment of the first and second substrates 100 and 200 from being separated (or reduce an amount or likelihood of such separation).

The shock absorber 320 may be disposed at an inner side of the inorganic sealant 310 (e.g., an inner side defined by the inorganic sealant 310). For example, the shock absorber 320 may be disposed closer to the LED 110 than the inorganic sealant 310 (e.g., the shock absorber 320 may be between the LED 110 and the inorganic sealant 310). Thus, when there is a shock on (or to) an inner side of the organic light-emitting display apparatus, the shock absorber 320 may efficiently absorb the shock (or a portion of the shock) before the shock reaches the inorganic sealant 310. However, a position of the shock absorber 320 is not limited thereto. For example, the shock absorber 320 may be disposed at an outer side or at both outer and inner sides of the inorganic sealant 310.

The shock absorber 320 may be formed of an organic material. For example, the organic material may be an organic material monomer including an acryl-based monomer, an epoxy-based monomer, or a silicon-based monomer.

In order to reduce the dead space and secure shock resistance reliability, a width w₂ of the shock absorber 320 may be about 0.08 to about 0.2 times the width w₀ of the non-display area NDA (e.g., a ratio of the width w₂ of the shock absorber 320 to the width w₀ of the non-display area NDA may be about 0.08 to about 0.2). For example, if the width w₀ of the non-display area NDA is in a range of about 1300 μm to about 1700 μm, the width w₂ of the shock absorber 320 may be in a range of about 150 μm to about 250 μm

The block member 410 may be disposed between the inorganic sealant 310 and the shock absorber 320. The block member 410 may prevent or block the shock absorber 320, which is relatively more mobile than the inorganic sealant 310, from contacting the inorganic sealant 310 (or reduce an amount or likelihood of such contact) during a method of manufacturing the organic light-emitting display apparatus. Therefore, the inorganic sealant 310 may be prevented from being contaminated by contacting the shock absorber 320 (or an amount or likelihood of such contamination may be reduced). When the inorganic sealant 310 is contaminated by the shock absorber 320, attachment by using a laser may weaken. However, according to an embodiment of the present invention, because the block member 410 prevents the inorganic sealant 310 from being contaminated by the shock absorber 320 (or reduces an amount or likelihood of such contamination), the attachment may be prevented from weakening (or an amount or likelihood of such weakening may be reduced).

The block member 410 may maintain a predetermined (or set) form so as to block movements of the shock absorber 320. To do so, the block member 410 may include (or be formed of) an inorganic material or an organic material. The inorganic material may be glass frit; and the organic material may be an acryl-based compound.

A material of the block member 410 may be the same (or substantially the same) material as that of the inorganic sealant 310. For example, if the inorganic sealant 310 includes glass frit, the block member 410 may include glass frit. Because the materials are the same (or substantially the same), while forming the inorganic sealant 310, the block member 410 may also be formed. Because the block member 410 and the inorganic sealant 310 may include the same (or substantially the same) material, the block member 410 may be easily formed without a separate additional process for forming the block member 410, and a manufacturing method may be simplified and manufacturing costs may be reduced.

A second block member 420 may be disposed between the shock absorber 320 and the LED 110. For example, the second block member 420 may be disposed closer to the LED 110 than the shock absorber 320. The second block member 420 may prevent or block the shock absorber 320 from contacting the LED 110 (or reduce an amount or likelihood of such contact) during the method of manufacturing the organic light-emitting display apparatus. Therefore, the LED 110 may be prevented from being contaminated by contacting the shock absorber 320 (or an amount or likelihood of such contamination may be reduced).

When applying the block member 410 and the second block member 420 to the first and second substrates 100 and 200, it may be advantageous (or necessary) to consider a size of the dead space and the attachment of the first and second substrates 100 and 200.

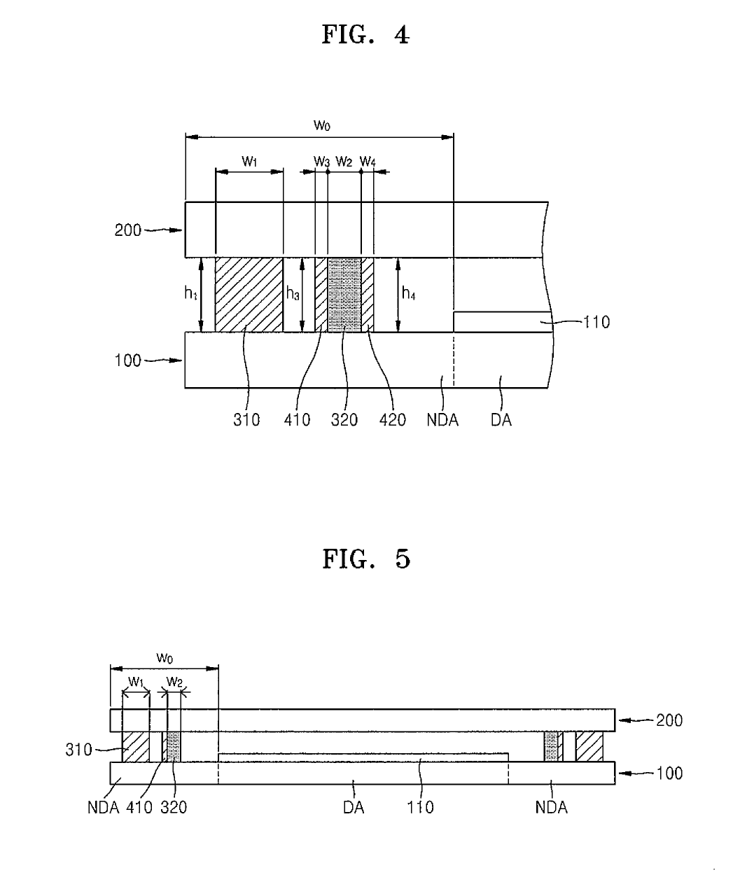

FIG. 4 is an enlarged cross-sectional view of a portion of the organic light-emitting display apparatus of FIG. 2. Referring to FIG. 4, in order to reduce the dead space and efficiently block the shock absorber 320, a width w₃ of the block member 410 may be about 0.05 times to about 0.2 times the width w₁ of the inorganic sealant 310 (e.g., a ratio of the width w₃ of the block member 410 to the width w₁ of the inorganic sealant 310 may be about 0.05 to about 0.2). For example, if the width w₁ of the inorganic sealant 310 is in a range of about 300 μm to about 700 μm, the width w₃ of the block member 410 may be in a range of about 40 μm to about 60 μm.

In order to reduce the dead space and efficiently block the shock absorber 320, a width w₄ of the second block member 420 may be about 0.05 times to about 0.2 times the width w₁ of the inorganic sealant 310 (e.g., a ratio of the width w₄ of the second block member 420 to the width w₁ of the inorganic sealant 310 may be about 0.05 to about 0.2). For example, if the width w₁ of the inorganic sealant 310 is in a range of about 300 μm to about 700 μm, the width w₄ of the second block member 420 may be in a range of about 40 μm to about 60 μm. The width w₄ of the second block member 420 may be the same as or different from the width w₃ of the block member 410.

The block member 410 may be formed to have a height that does not hinder the attachment of the first and second substrates 100 and 200, which are attached together by the inorganic sealant 310. For example, while the first and second substrates 100 and 200 are both flat, as shown in FIG. 4, when the block member 410 and the inorganic sealant 310 are disposed between the first and second substrates 100 and 200, a height h₃ of the block member 410 may be formed to not be greater than a height h₁ of the inorganic sealant 310. For example, the height h₃ of the block member 410 may be less than or equal to (e.g., the same as) the height h₁ of the inorganic sealant 310 (e.g., h₃≦h₁). If the height h₃ of the block member 410 is greater than the height h₁ of the inorganic sealant 310, the inorganic sealant 310 may not stably attach to at least one of the first and second substrates 100 and 200, and accordingly, the attachment of the first and second substrates 100 and 200 may be hindered.

The second block member 420 may also be formed to not hinder the attachment of the first and second substrates 100 and 200 together by the inorganic sealant 310. For example, a height h₄ of the second block member 420 may be formed to not be greater than the height h₁ of the inorganic sealant 310. For example, the height h₄ of the second block member 420 may be less than or equal to (e.g., the same as) the height h₁ of the inorganic sealant 310 (e.g., h₄≦h₁). The height h₄ of the second block member 420 may be equal to (e.g., the same as) or different from the height h₃ of the block member 410.

The embodiments described above provide examples in which the block member 410 and the second block member 420 are formed at two sides, respectively, of the shock absorber 320, but the present invention is not limited thereto and the second block member 420 may be selectively applied if desired (or necessary). For example, as in FIG. 5, the second block member 420 may be omitted from the organic light-emitting display apparatus.

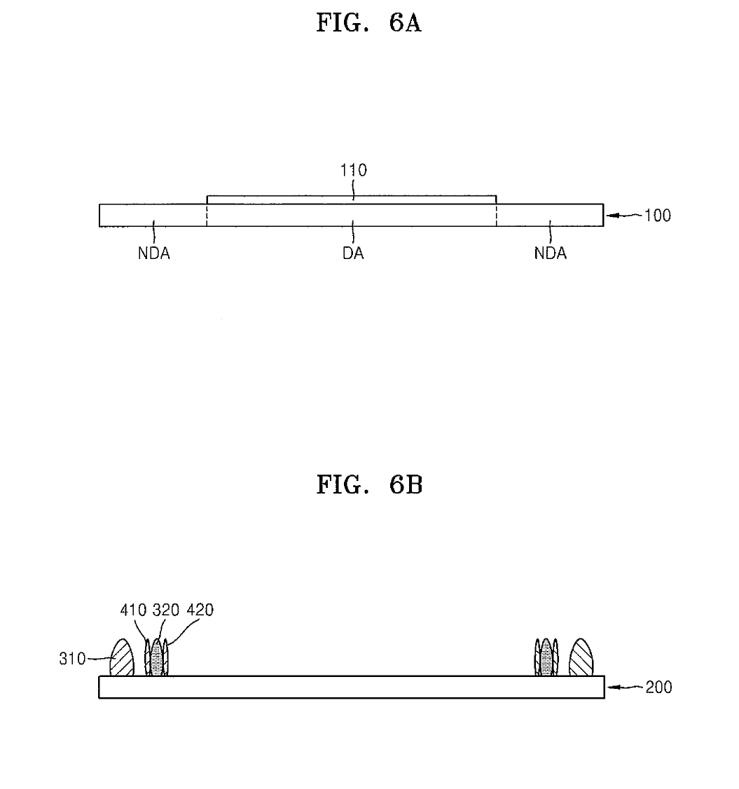

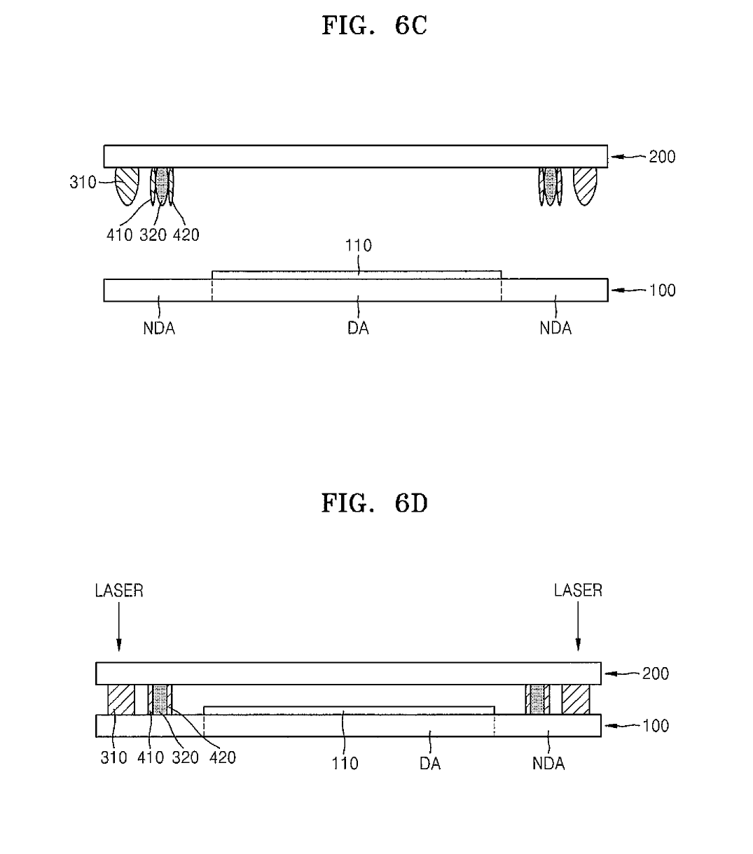

FIGS. 6A to 6D are cross-sectional views illustrating a method of manufacturing the organic light-emitting display apparatus of FIG. 2, according to an embodiment of the present invention.

Referring to FIG. 6A, the first substrate 100, on which the plurality of LEDs 110 are formed, is provided (or prepared). The first substrate 100 may include the display area DA in which the LED 110 is formed, the non-display area NDA surrounding the display area DA, and a pad area provided at a side of the non-display area NDA.

Referring to FIG. 6B, the second substrate 200 for sealing the LED 110 of the display area DA is prepared. The second substrate 200 may be formed so that the second substrate 200 overlaps portions of the display area DA and the non-display area NDA of the first substrate 100.

The inorganic sealant 310 is continuously formed along an outer region of the second substrate 200 (as shown in FIG. 1). The inorganic sealant 310 may be formed of glass frit, and may be formed by dispensing, screen printing, or other deposition processes, but the inorganic sealant 310 is not limited thereto.

The block member 410 and the second block member 420 are formed such that the block member 410 and the second block member 420 are separated from the inner side of the inorganic sealant 310 (e.g., the inner side defined by the inorganic sealant 310). The block member 410 and the second block member 420 are continuously formed around an edge of the LED 110. At least one of the block member 410 and the second block member 420 may be formed of the same (or substantially the same) material as that of the inorganic sealant 310. For example, the material of the block member 410 and the second block member 420 may be glass frit. By forming at least one of the block member 410 and the second block member 420 of the same (or substantially the same) material as the inorganic sealant 310, the inorganic sealant 310 and at least one of the block member 410 and the second block member 420 may be concurrently (e.g., simultaneously) formed in a single process.

To stably attach the first and second substrates 100 and 200 by using the inorganic sealant 310, the height h₃ of the block member 410 and the height h₄ of the second block member 420 may be less than or equal to (e.g., the same as) the height h₁ of the inorganic sealant 310.

Also, in order to reduce the dead space and efficiently block the shock absorber 320, the width w₃ of the block member 410 may be about 0.05 times to about 0.2 times the width w₁ of the inorganic sealant 310 (e.g., a ratio of the width w₃ of the block member 410 to the width w₁ of the inorganic sealant 310 may be about 0.05 to about 0.2). For example, if the width w₁ of the inorganic sealant 310 is in a range of about 300 μm to about 700 μm, the width w₃ of the block member 410 may be in a range of about 40 μm to about 60 μm.

In order to reduce the dead space and efficiently block the shock absorber 320, the width w₄ of the second block member 420 may be about 0.05 times to about 0.2 times the width w₁ of the inorganic sealant 310 (e.g., a ratio of the width w₄ of the second block member 420 to the width w₁ of the inorganic sealant 310 may be about 0.05 to about 0.2). For example, if the width w₁ of the inorganic sealant 310 is in a range of about 300 μm to about 700 μm, the width w₄ of the second block member 420 may be in a range of about 40 μm to about 60 μm. The width w₄ of the second block member 420 may be equal to (e.g., the same as) or different from the width w₃ of the block member 410.

Next, the shock absorber 320 is formed between the block member 410 and the second block member 420. For example, the shock absorber 320 may be formed to be disposed at an inner side of the block member 410 and at an outer side of the second block member 420 (e.g., an inner side defined by the block member 410 and an outer side defined by the second block member 420). By forming the shock absorber 320 at the inner side of the block member 410, the shock absorber 320 may be prevented from contacting the inorganic sealant 310 that is formed at an outer side of the block member 410 (or an amount or likelihood of such contact may be reduced). By forming the shock absorber 320 at the outer side of the second block member 420, the shock absorber 320 may be prevented from contacting the LED 110 that is disposed at the inner side of the second block member 420 (or an amount or likelihood of such contact may be reduced).

The shock absorber 320 may be formed of an organic material. For example, the organic material may be an organic material monomer including an acryl-based monomer, an epoxy-based monomer, or a silicon-based monomer, but the shock absorber is not limited thereto. The shock absorber 320 may have a greater viscosity than the inorganic sealant 310, the block member 410, and the second block member 420.

Referring to FIG. 6C, the second substrate 200 is disposed on the first substrate 100 so as to face the first substrate 100. For example, the inorganic sealant 310, the block member 410, the shock absorber 320 and the second block member 420 of the second substrate 200 may be formed to face the first substrate 100. The first substrate 100 may be disposed so that the LED 110 faces the second substrate 200.

Referring to FIG. 6D, the first and second substrates 100 and 200 are attached together. As the first and second substrates 100 and 200 are attached together, the inorganic sealant 310, the block member 410, the shock absorber 320 and the second block member 420 may contact the first substrate 100.

While the inorganic sealant 310 is contacting the first and second substrates 100 and 200, a laser beam is irradiated along the inorganic sealant 310. As a result of the heat that is generated as the laser beam is absorbed, the inorganic sealant 310 melts, and thus, the inorganic sealant 310 attaches the first and second substrates 100 and 200 together, and the LED 110 is sealed from the outside. Because the inorganic sealant 310 is not contaminated by the shock absorber 320 (or an amount or likelihood of such contamination is reduced), the inorganic sealant 310 may be stably attached to the first and second substrates 100 and 200.

When attaching the first and second substrates 100 and 200 together, the block member 410 and the second block member 420 may block the shock absorber 320 from contacting the inorganic sealant 310 and the LED 110 (or reduce an amount or likelihood of such contact).

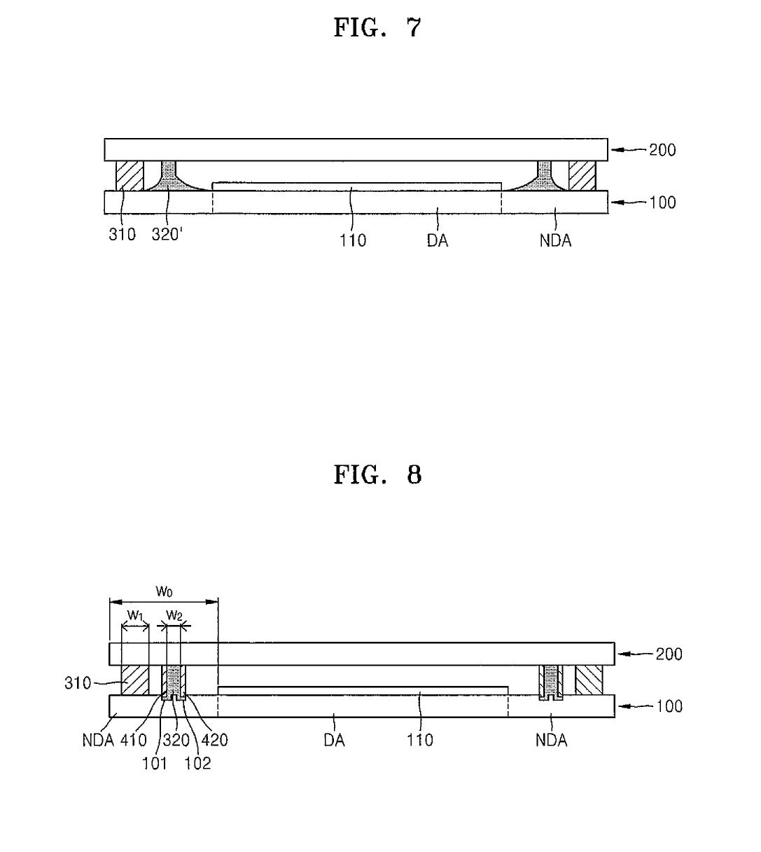

FIG. 7 is a cross-sectional view illustrating an attachment state of the first and second substrates 100 and 200 when the block member 410 and the second block member 420 are not included, in contrast to the above-described embodiments of the present invention. Referring to FIG. 7, when the block member 410 and the second block member 420 are not included, the shock absorber 320′, which has a smaller viscosity than the inorganic sealant 310, may move and contact the inorganic sealant 310 and the LED 110. In this case, because the inorganic sealant 310 is contaminated by the shock absorber 320, when curing the inorganic sealant 310 by irradiating a laser beam or infrared rays, the inorganic sealant 310 may not be completely attached to the first substrate 100, and accordingly, the sealing state may be inadequate or unsuitable. Accordingly, the inorganic sealant 310 may easily be detached from (or come off from) the first substrate 100 due to a shock. Also, because the LED 110 is contaminated by the shock absorber 320, the light-emission efficiency of the LED 110 may be decreased. Thus, the organic light-emitting display apparatus may be less reliable.

However, according to embodiments of the present invention, the block member 410 is formed between the inorganic sealant 310 and the shock absorber 320, and the second block member 420 is formed between the shock absorber 320 and the LED 110, so as to prevent the inorganic sealant 310 and the LED 110 from being contaminated (or to reduce an amount or likelihood of such contamination).

In the embodiments described above, the inorganic sealant 310, the block member 410, the shock absorber 320, and the second block member 420 are all formed as a single structure. However, they are not limited thereto, and the inorganic sealant 310, the block member 410, the shock absorber 320, and the second block member 420 may be two or more structures.

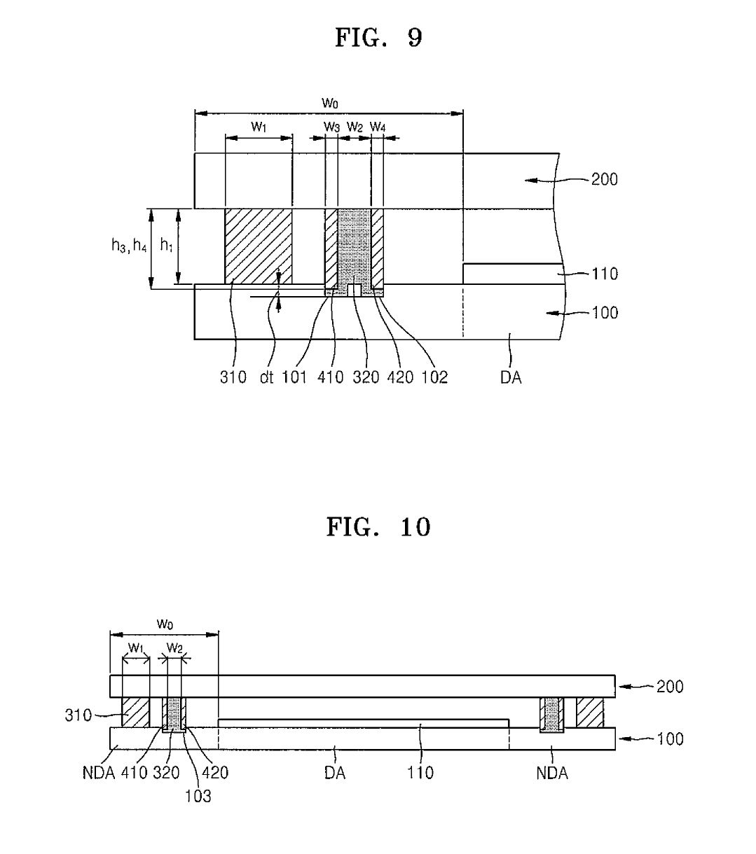

FIG. 8 is a cross-sectional view of an organic light-emitting display apparatus according to another embodiment of the present invention. FIG. 9 is an enlarged cross-sectional view of a portion of the organic light-emitting display apparatus of FIG. 8.

Referring to FIG. 8, the organic light-emitting display apparatus may include the first substrate 100, on which the plurality of LEDs 110 are formed; the second substrate 200 disposed to face (e.g., facing) the first substrate 100; the inorganic sealant 310 disposed between the first and second substrates 100 and 200 so as to surround the plurality of LEDs 110; the shock absorber 320 disposed at the inner side of the inorganic sealant 310; and the block member 410 and the second block member 420 disposed at the both sides of the shock absorber 320. The elements and the configurations of the organic light-emitting display apparatus of FIG. 8 that are the same as the organic light-emitting display apparatus of FIG. 2 described above are not repeatedly described, and only the difference therebetween is described here.

Referring to FIG. 9, trenches 101 and 102 may be formed in the first substrate 100. A portion of the shock absorber 320 may be inserted in the trenches 101 and 102. By inserting or accommodating a portion of the shock absorber 320 in the trenches 101 and 102, the shock absorber 320 may be prevented from horizontally moving on the first substrate 100 (or an amount or likelihood of such movement may be reduced). For example, during the process of attaching the first and second substrates 100 and 200, the shock absorber 320 may be blocked from moving in a direction of the inorganic sealant 310 (or an amount or likelihood of such movement may be reduced), firstly by the trench 101, and secondly by the block member 410. Therefore, it is possible to further block the shock absorber 320 from contacting inorganic sealant 310 (or to reduce an amount or likelihood of such contact). Because the trenches 101 and 102 are formed in the first substrate 100 on which the LED 110 is formed, the trenches 101 and 102 may be concurrently (e.g., simultaneously) formed with the LED 110. For example, the trenches 101 and 102 may be formed by using a process of forming a contact hole, but the trenches are not limited thereto. Thus, the trenches 101 and 102 may be easily formed without a performing a separate additional process.

A portion of the block member 410 may be inserted in the trench 101. Because a portion of the block member 410 is inserted in the trench 101, the height h₃ of the block member 410 may be increased. For example, the height h₃ of the block member 410 may be greater than the height h₁ of the inorganic sealant 310. By increasing the height h₃ of the block member 410, it is possible to more efficiently block the shock absorber 320 from moving in the direction of the inorganic sealant 310 (or to reduce an amount or likelihood of such movement) before attaching the first and second substrates 100 and 200 together. Even during the process of attaching the first and second substrates 100 and 200 together, it is possible to more efficiently block the shock absorber 320 from moving in the direction of the inorganic sealant 310 (or to reduce an amount or likelihood of such movement).

When the height h₃ of the block member 410 is greater than the height h₁ of the inorganic sealant 310, a depth dₜ of the trench 101 may be greater than the difference (h₃−h₁) between the height h₃ of the block member 410 and the height h₁ of the inorganic sealant 310 (h₃−h₁<dₜ). Accordingly, a portion of the block member 410 and a portion of the shock absorber 320 may be inserted in the trench 101. For example, the depth dₜ of the trench 101 may be in a range of about 1 μm to about 3 μm. A width of the trench 101 may be greater than the width w₃ of the block member 410 so that a portion of the shock absorber 320 may be inserted in the trench 101.

A portion of the second block member 420 may be inserted in the trench 102. Because a portion of the second block member 420 is inserted in the trench 102, the height h₄ of the second block member 420 may be increased. For example, the height h₄ of the second block member 420 may be greater than the height h₁ of the inorganic sealant 310. By increasing the height h₄ of the second block member 420, it is possible to more efficiently block the shock absorber 320 from moving in a direction of the LED 110 (or to reduce an amount or likelihood of such movement) before attaching the first and second substrates 100 and 200 together. Even during the process of attaching the first and second substrates 100 and 200 together, it is possible to more efficiently block the shock absorber 320 from moving in the direction of the LED 110 (or to reduce an amount or likelihood of such movement).

When the height h₄ of the second block member 420 is greater than the height h₁ of the inorganic sealant 310, a depth d₁ of the trench 102 may be greater than the difference (h₄−h₁) between the height h₄ of the second block member 420 and the height h₁ of the inorganic sealant 310 (h₄−h₁<dₜ). Accordingly, a portion of the second block member 420 and a portion of the shock absorber 320 may be inserted in the trench 102. For example, the depth dₜ of the trench 102 may be in a range of about 1 μm to about 3 μm. A width of the trench 102 may be greater than the width w₄ of the second block member 420 so that a portion of the shock absorber 320 may be inserted in the trench 102. The respective depths and widths of the trenches 101 and 102 may be the same or different.

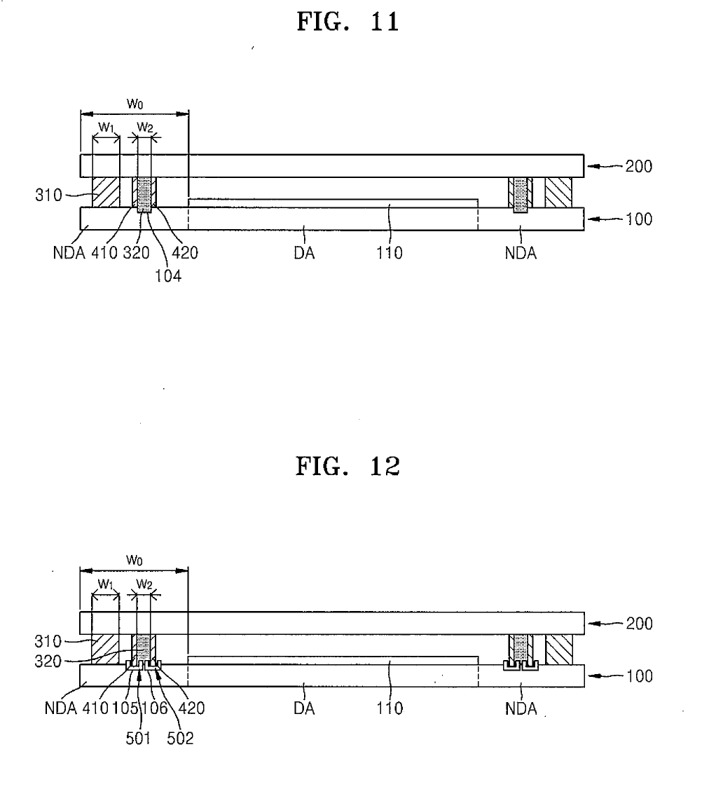

In FIGS. 8 and 9, a case where the trenches 101 and 102 are formed in locations of the first substrate 100 that respectively correspond to the block member 410 and the second block member 420, are illustrated. However, the forms of the trenches 101 and 102 are not limited thereto and may be modified in various ways. As an example, as shown in FIG. 10, a trench 103 may be formed as a single structure so as to correspond to the block member 410, the shock absorber 320, and the second block member 420. In this case, a width of the trench 103 may be equal to (e.g., the same as) the respective widths w₂, w₃ and w₄ of the shock absorber 320, the block member 410, and the second block member 420; however, the respective heights h₃ and h₄ of the block member 410 and the second block member 420 may be greater than the height h₁ of the inorganic sealant 310. As another example, as shown in FIG. 11, a trench 104 may be formed as a single structure so as to have a width corresponding to the width w₂ of the shock absorber 320 so that a portion of the shock absorber 320 is inserted, but the block member 410 and the second block member 420 are not inserted. In this case, the width of the trench 104 may be less than or equal to (e.g., the same as) the width w₂ of the shock absorber 320. The respective heights h₃ and h₄ of the block member 410 and the second block member 420 may be less than or the same as the height h₁ of the inorganic sealant 310.

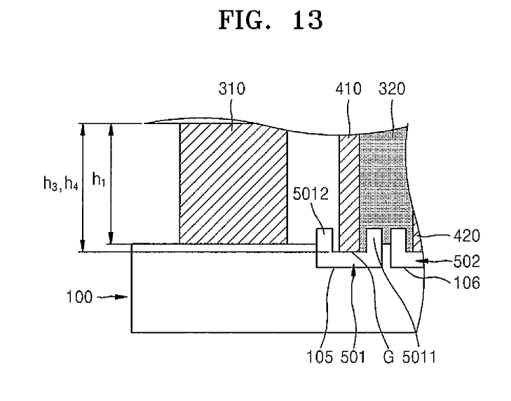

FIG. 12 is a cross-sectional view of an organic light-emitting display apparatus according to another embodiment of the present invention. FIG. 13 is an enlarged cross-sectional view of a portion of the organic light-emitting display of FIG. 12. The elements and the configurations of the organic light-emitting display apparatus of FIG. 12 that are the same as the organic light-emitting display apparatus of FIGS. 8 to 11 described above are not repeatedly described, and only the difference therebetween is described here.

Referring to FIG. 12, structures (e.g., supports) 501 and 502 may be disposed on the first substrate 100. For example, trenches 105 and 106 may be formed in the first substrate 100, and the structures 501 and 502 may be inserted in the trenches 105 and 106, respectively. A portion of the block member 410 and a portion of the second block member 420 may be inserted in the structures 501 and 502, respectively. Functions of the structure (e.g., support) 501, in which a portion of the block member 410 is inserted, are similar to functions of the structure (e.g., support) 502, in which a portion of the second block member 420 is inserted. Therefore, the structure 501, in which a portion of the block member 410 is inserted, is mainly described hereinafter.

Referring to FIG. 13, a groove G, in which a portion of the block member 410 may be inserted, is formed in the structure 501. On both sides of the groove G, a first protrusion 5011 and a second protrusion 5012 that protrude from the first substrate 100 are formed. The structure 501 may efficiently block the shock absorber 320 from moving in the direction of the inorganic sealant 310 (or reduce an amount or likelihood of such movement). The shock absorber 320 is blocked from moving in the direction of the inorganic sealant 310 (or an amount or likelihood of such movement is reduced), firstly by the first protrusion 5011, secondly by the block member 410, and thirdly by the second protrusion 5012.

Similarly to the structure 501 described above, a groove, a first protrusion, and a second protrusion may be formed in the structure 502 in which a portion of the second block member 420 is inserted. Thus, it is possible to efficiently block the shock absorber 320 from moving in the direction of the LED 110 (or to reduce an amount or likelihood of such movement).

Materials of the structures 501 and 502 may be a photoresist, but the structures 501 and 502 are not limited thereto. Because the photoresist is a material that is generally used in the process of forming the LED 110, the structures 501 and 502 may be easily formed on the first substrate 100 without performing separate additional processes.

In the embodiments of the present invention described above, an example in which the structures 501 and 502 that are disposed on the first substrate 100 and are inserted in the trenches 105 and 106 of the first substrate 100 is mainly described. However, the structures 501 and 502 are not limited thereto, and may be formed on the first substrate 100 that is flat and does not have the trenches 105 and 106 formed therein.

The organic light-emitting display apparatuses of FIGS. 8 to 13 may be manufactured by partially modifying the manufacturing method described with reference to FIGS. 6A to 6D. As an example, the organic light-emitting display apparatuses of FIGS. 8 to 13 may be manufactured by forming the trenches 101, 102, 103, and 104 in predetermined (or set) forms, as described in FIGS. 8 to 11, in the first substrate 100, and then proceeding with the same (or substantially the same) processes as described with respect to FIGS. 6B to 6D. The trenches 101, 102, 103 and 104 may be concurrently (e.g., simultaneously) formed with the contact hole during the process of forming the LED 110. As another example, the organic light-emitting display apparatuses of FIGS. 12 to 13 may be manufactured by forming the trenches 105 and 106 of predetermined (or set) forms on the first substrate 100, forming the structures 501 and 502 in the trenches 105 and 106, and then proceeding with the same (or substantially the same) processes as described with respect to FIGS. 6B to 6D. The trenches 105 and 106 and the structures 501 and 502 may be formed during the process of forming the LED 110.

As described above, according to one or more of the above embodiments of the present invention, in an organic light-emitting display apparatus, shock resistance reliability is improved and attachment between an upper substrate and a lower substrate is prevented from weakening (or an amount or likelihood of weakening of attachment between an upper substrate and a lower substrate is reduced).

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims, and equivalents thereof.

What is claimed is:

1. An organic light-emitting display apparatus comprising:
a first substrate comprising at least one organic light-emitting diode (OLED);
a second substrate facing the first substrate;
an inorganic sealant between the first and second substrates and attaching the first and second substrates together;
a shock absorber between the first and second substrates and configured to absorb a shock applied to at least one of the first and second substrates; and
a block member between the inorganic sealant and the shock absorber and configured to separate the shock absorber from the inorganic sealant.

2. The organic light-emitting display apparatus of claim 1, wherein the block member and the inorganic sealant are formed of a same material.

3. The organic light-emitting display apparatus of claim 1, wherein the block member is less than or equal to the inorganic sealant in height.

4. The organic light-emitting display apparatus of claim 1, wherein a ratio of a width of the block member to a width of the inorganic sealant is about 0.05 to about 0.15.

5. The organic light-emitting display apparatus of claim 1, wherein the shock absorber comprises an organic material.

6. The organic light-emitting display apparatus of claim 1, wherein the shock absorber is between the OLED and the inorganic sealant.

7. The organic light-emitting display apparatus of claim 1, further comprising a second block member between the OLED and the shock absorber.

8. The organic light-emitting display apparatus of claim 1, wherein the first substrate has a trench, and wherein a portion of the shock absorber is inserted in the trench.

9. The organic light-emitting display apparatus of claim 8, wherein a portion of the block member is inserted in the trench.

10. The organic light-emitting display apparatus of claim 9, wherein a height of the block member is greater than a height of the inorganic sealant.

11. The organic light-emitting display apparatus of claim 10, wherein a difference between the height of the block member and the height of the inorganic sealant is less than a depth of the trench.

12. The organic light-emitting display apparatus of claim 8, wherein a depth of the trench is in a range of about 1 μm to about 3 μm.

13. The organic light-emitting display apparatus of claim 1, wherein a portion of the block member is inserted in a support on the first substrate.

14. The organic light-emitting display apparatus of claim 8, wherein a portion of the block member is inserted in a support on the trench.

15. The organic light-emitting display apparatus of claim 1, wherein the first substrate comprises a display area comprising the OLED, and a non-display area surrounding the display area, and
wherein a ratio of a width of the inorganic sealant to a width of the non-display area is about 0.15 to about 0.55.

16. The organic light-emitting display apparatus of claim 1, wherein the first substrate comprises a display area comprising the OLED, and a non-display area surrounding the display area, and
wherein a ratio of a width of the shock absorber to a width of the non-display area is about 0.08 to about 0.2.

17. A method of manufacturing an organic light-emitting display apparatus, the method comprising:
providing a first substrate and at least one organic light-emitting diode (OLED) on the first substrate;
providing an inorganic sealant, a block member, and a shock absorber on a second substrate;
positioning the inorganic sealant on the second substrate to face the first substrate; and
attaching the first and second substrates together.

18. The method of claim 17, wherein the block member is between the inorganic sealant and the shock absorber.

19. The method of claim 17, wherein the inorganic sealant and the block member are formed of a same material.

20. The method of claim 17, wherein the providing of the shock absorber on the second substrate comprises providing the shock absorber at an inner side of the inorganic sealant, and
further providing a second block member at an inner side of the shock absorber.
